(19) United States
(12) Patent Application Publication
(10) Pub. No.: US 2010/0062600 A1
(43) Pub. Date: Mar. 11, 2010

(54) Method of manufacturing a semiconductor device

(75) Inventor: Tomokatsu Utsuki, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/585,022

(22) Filed: Sep. 1, 2009

(30) Foreign Application Priority Data
Sep. 8, 2008 (JP) 2008-230291

(51) Int. Cl. H01L 21/768

(52) U.S. Cl. 438/675; 257/E21.586

(57) ABSTRACT

A method of manufacturing a semiconductor device includes the steps of forming a first insulating layer with a first opening; forming a first redistribution layer having a first via with a recess; forming a second insulating layer with a second opening on the first redistribution layer so that the second opening causes a part of the first redistribution layer including the recess to be exposed; depositing a conductive material layer and a photoresist film; irradiating a first area of the photoresist film with first exposure light, and irradiating a second area of the photoresist film with second exposure light, wherein the first area includes the second area and the second area includes an area corresponding to the first via; developing the photoresist film; and causing the conductive material layer to grow through a plating process, thereby forming the second redistribution layer having a second via stacked on the first via.

### BACKGROUND OF THE INVENTION

1. Field of the Invention

The present invention relates to a method of manufacturing a semiconductor device, in particular, a method of manufacturing a wafer level chip size package (WCSP) having a multilayer redistribution structure.

2. Description of the Related Art

In recent years, there has been increasing demand for a small-sized thin-type integrated circuit package, in which a semiconductor chip such as a semiconductor integrated circuit is packaged, and therefore the development of the chip size package (CSP) having bumps as spherical external connecting terminals arranged in matrix on its surface is proceeding.

A CSP obtained by singulating (or dicing) a structure including a plurality of semiconductor devices formed in a semiconductor wafer through a wafer process is referred to as a wafer level chip size package (WCSP). In recent years, the WCSP also introduces a multilayer redistribution structure for the purpose of realizing high integration. Furthermore, there is a proposal of a stacked via structure, in which the WCSP having a multilayer redistribution structure adopts a multilayer structure including stacked vias on an electrode pad for the purpose of realizing higher integration, for example, in patent document 1 (Japanese Patent Kokai Publication No. 2002-252310).

As illustrated in FIGS. 1A-1C, the conventional stacked via structure is formed through a process of forming an electrode pad 12 disposed on a semiconductor substrate 10, a passivation film 14, a first insulating layer 16 with a first opening, a first redistribution layer 18 with a first via 18a, a second insulating layer 20 with a second opening 20a, a second seed layer 30, a second conductive material layer 32, and a resist film 34, a process of irradiating the above structure with exposure light 38 using a light-shielding mask 36 (FIG. 1A), a process of developing the resist film 34 (FIG. 1B), and a process of forming a second redistribution layer 22 (FIG. 1C).

In the conventional manufacturing method, the light-exposed area of the resist film 34 is intended to be removed completely in order to cause a second conductive material layer 32 to grow properly through a plating process and to form the second redistribution layer 22 of a desired pattern electrically connecting the first redistribution layer.

However, in the process of developing the resist film 34 (FIG. 1B), there often occurs a problem that a residual is left in a recess 18b of the first via 18a as illustrated in FIG. 2 as a part 34a or FIG. 3 as a part 34b. If the residual is left in the recess 18b of the first via 18a, the second conductive material layer 32 cannot grow properly through a plating process and therefore the second redistribution layer 22 of a desired pattern electrically connecting the first redistribution layer cannot be obtained.

In order to resolve this problem, it is conceivable to increase the exposure light amount to the resist film 34. However, if the exposure light amount is too excessive, the exposure light reaches a part of the resist film 34 outside the first via 18 and therefore the second redistribution layer 22 of a desired pattern cannot be obtained.

### SUMMARY OF THE INVENTION

The object of the present invention is to provide a method of manufacturing a semiconductor device that can cause a second conductive material layer to grow properly through a plating process, thereby forming the second redistribution layer of a desired pattern electrically connecting the first redistribution layer.

According to the present invention, a method of manufacturing a semiconductor device includes the steps of forming a first insulating layer with a first opening on a semiconductor substrate; forming a first redistribution layer having a first via inside the first opening on the semiconductor substrate and the first insulating layer, an upper surface of the first via having a recess; forming a second insulating layer with a second opening on the first redistribution layer so that the second opening causes a part of the first redistribution layer including the recess to be exposed; depositing a conductive material layer so as to cover the exposed part of the first redistribution layer; depositing a photoresist film so as to cover the conductive material layer; irradiating a first area of the photoresist film corresponding to an area where a second redistribution layer is to be formed with first exposure light, and irradiating a second area of the photoresist film with second exposure light, wherein the first area includes the second area and the second area includes an area corresponding to the first via; developing the photoresist film to remove a part of the photoresist film inside the first area, thereby causing the conductive material layer to be exposed; and causing the conductive material layer to grow through a plating process, thereby forming the second redistribution layer having a second via stacked on the first via.

According to a method of manufacturing a semiconductor device of the present invention, since a residual of the resist film can be removed properly from an upper surface of a first via, the second redistribution layer of a desired pattern electrically connecting the first redistribution layer can be obtained.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1A-1C are schematic partial cross sectional views illustrating processes in a conventional method of manufacturing a WCSP;

FIG. 2 is an explanatory diagram illustrating a problem in the conventional method;

FIG. 3 is an explanatory diagram illustrating another problem in the conventional method;

FIGS. 4A-4D are schematic partial cross sectional views illustrating processes in a method of manufacturing a WCSP according to an embodiment of the present invention;

FIG. 5 is a schematic partial cross sectional view illustrating a process of forming a resist film in the method of manufacturing a WCSP according to the embodiment of the present invention;

FIG. 6 is a schematic partial cross sectional view illustrating a process of irradiating a first area of the resist film with first exposure light in the method of manufacturing a WCSP according to the embodiment of the present invention;

FIG. 7 is a schematic partial cross sectional view illustrating a process of irradiating a second area of the resist film with second exposure light in the method of manufacturing a WCSP according to the embodiment of the present invention;

FIG. 8 is a schematic partial cross sectional view illustrating a process of developing the light-exposed resist film to remove it in the method of manufacturing a WCSP according to the embodiment of the present invention;

FIG. 9 is a schematic partial cross sectional view illustrating a process of forming a second redistribution layer in the method of manufacturing a WCSP according to the embodiment of the present invention;

FIG. 10 is a schematic partial cross sectional view illustrating a process of forming a post electrode and a protective film in the method of manufacturing a WCSP according to the embodiment of the present invention;

FIG. 11 is a schematic partial cross sectional view illustrating a process of planarizing the post electrode and the protective film in the method of manufacturing a WCSP according to the embodiment of the present invention; and

FIG. 12 is a schematic partial cross sectional view illustrating a process of forming a bump as an external connecting terminal in the method of manufacturing a WCSP according to the embodiment of the present invention; and

FIG. 13 is a schematic partial cross sectional view illustrating a process of forming a third redistribution layer process in a modified method of manufacturing a WCSP according to the embodiment of the present invention.

### DETAILED DESCRIPTION OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications will become apparent to those skilled in the art from the detailed description.

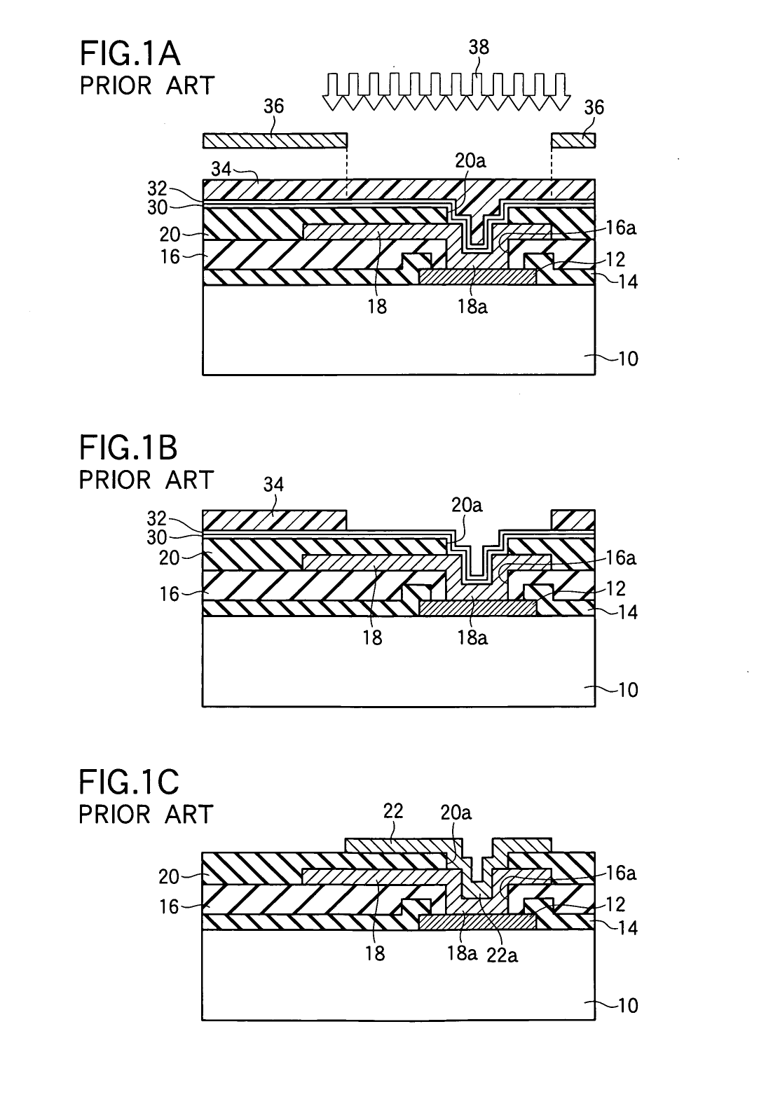

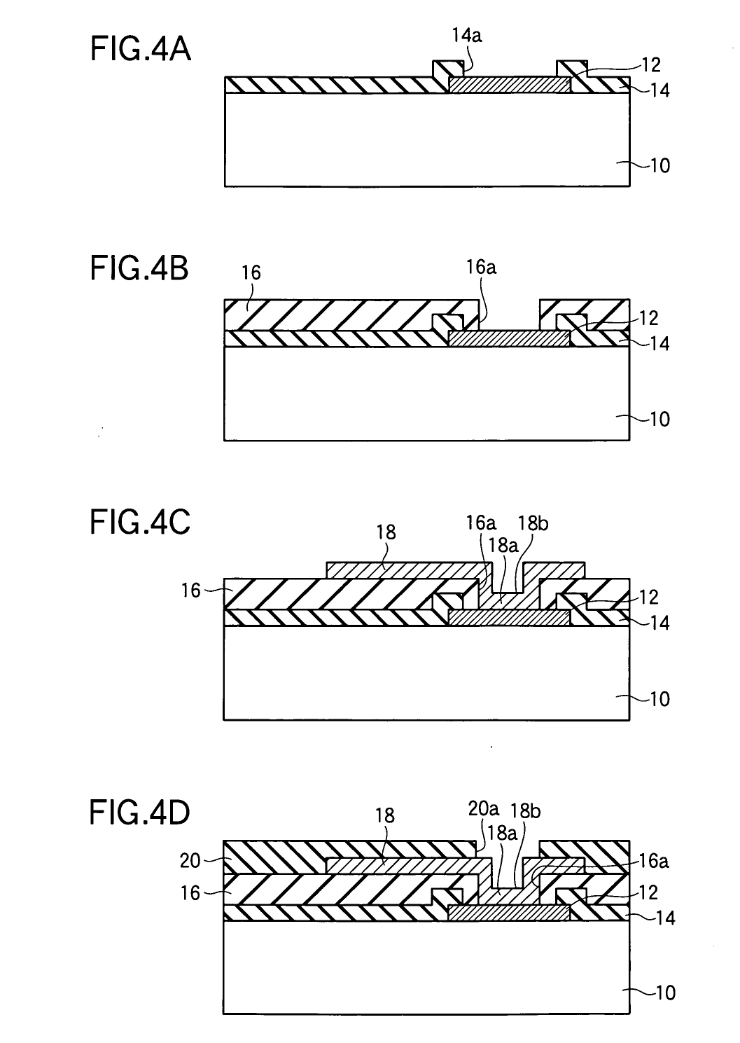

A method of manufacturing a semiconductor device according to an embodiment of the present invention relates to an improvement over the conventional manufacturing-method that has already been described with reference to FIGS. 1A-1C. A description will be made as to an example of the method of manufacturing a WCSP as a semiconductor device according to the embodiment of the present invention with reference to FIGS. 4A-4D and FIG. 5 to FIG. 13.

FIGS. 4A-4D and FIG. 6 to FIG. 13 are schematic partial cross sectional views illustrating processes in the method of manufacturing the WCSP according to the embodiment of the present invention. Although these figures illustrate partial structures including only one electrode pad 12 of the WCSP, the WCSP as an actual product includes a plurality of electrode pads. Furthermore, in FIGS. 4A-4D and FIG. 5 to FIG. 13, components that are the same as or correspond to the components shown in FIGS. 1A-1C, FIG. 2 and FIG. 3 are assigned the same reference numerals.

First, referring to FIG. 4A, an electrode pad 12 is formed on an upper surface of a semiconductor wafer 10 such as a silicon wafer or the like. A plurality of the semiconductor chips (not shown in the figures) are formed in the semiconductor wafer 10. Although a single electrode pad 12 is shown in the figures, actually, a plurality of the electrode pads 12 is formed on the upper surface of the semiconductor wafer 10. Each electrode pad 12 is electrically connected to a circuit (not shown in the figures) formed in the semiconductor wafer 10. The electrode pad 12 can be a layer made of a conductive material such as aluminum or the like.

Next, referring to FIG. 4A, a passivation film 14 is formed on the semiconductor wafer 10 and the electrode pad 12 so as to have an opening 14a which causes a part of the electrode pad 12 to be exposed. The passivation film 14 can be made of an insulating material such as phosphosilicate glass (PSG), silicon oxide (SiO₂), silicon nitride (Si₃N₄), or the like. The passivation film 14 is formed by evaporating a film through a film forming process of such material using a chemical vapor deposition (CVD) method and thereafter etching a part of the evaporated film to form a predetermined pattern.

Next, referring to FIG. 4B, a first insulating layer 16 is formed on the upper surfaces of the passivation film 14 and the electrode pad 12 by, for example, spin-coating a photosensitive resin material (e.g., PBO or the like. After that, by a light-exposure and developing process, a first opening 16a is formed in the first insulating layer 16. The first insulating layer 16 is made of, for example, a polymer type insulating material or the like. It is preferable to adopt photosensitive polybenzoxazoles (PBO) or the like, to which the light-exposure and developing process can be applied, as the polymer type insulating material. If the first insulating layer 16 is photosensitive, the first opening 16a can be formed by the light-exposure and developing process of the first insulating layer 16.

Next, referring to FIG. 4C, a first redistribution layer 18 is formed so as to be in contact with the exposed upper surface of the electrode pad 12. At this time, a part of the first redistribution layer 18 formed inside the first opening 16a is disposed at a lower level than an under surface of the first insulating layer 16 and is referred to as a first via 18a. The first via 18a of the first redistribution layer 18 has a recess 18b around a center of an upper surface of the first via 18a. The first redistribution layer 18 is made of a conductive material such as copper (Cu) or the like. The first redistribution layer 18 can be formed by causing a part of a conductive material layer to grow through a plating process and patterning the grown part of the first redistribution layer 18 to have a predetermined pattern, in a similar manner to a second redistribution layer 22 which will be described later.

The first redistribution layer 18 is formed as follows, for example. First, a first seed layer (not shown in the figures) made of, for example, titanium (Ti), a first conductive material layer (not shown in the figures) made of, for example, copper (Cu) which will be a lower-side part of the first redistribution layer 18, and a resist film (not shown in the figures) are sequentially deposited on the first insulating layer 16 and the upper surface of the electrode pad 12. Next, by a light-exposure and developing process as a patterning process, the resist film is subjected a patterning process to form a desired redistribution pattern (not shown in the figures). After that, a part of the first conductive material layer, which is not covered by the resist film, is caused to grow through a plating process to form the first redistribution layer 18. Finally, the resist film, a part of the first conductive material layer other than the grown part of the first redistribution layer 18, and a part of the first seed layer are sequentially removed, thereby forming the structure shown in FIG. 4C.

Next, referring to FIG. 4D, a second insulating layer 20 made of, for example, photosensitive PBO or the like is formed on an upper surface of the structure shown in FIG. 4C so as to cover a predetermined area of the upper surface of the first redistribution layer 18. After that, by a light-exposure and developing process, a second opening 20a which causes the first via 18a with the recess 18b to be exposed is formed in the second insulating layer 20. The second insulating layer 20 is made of, for example, a polymer type insulating material. It is preferable to adopt PBO or the like, to which a light-exposure and developing process can be applied, as the polymer type insulating material. If the second insulating layer 20 is photosensitive, the second opening 20a can be formed by a light-exposure and developing process of the second insulating layer 20.

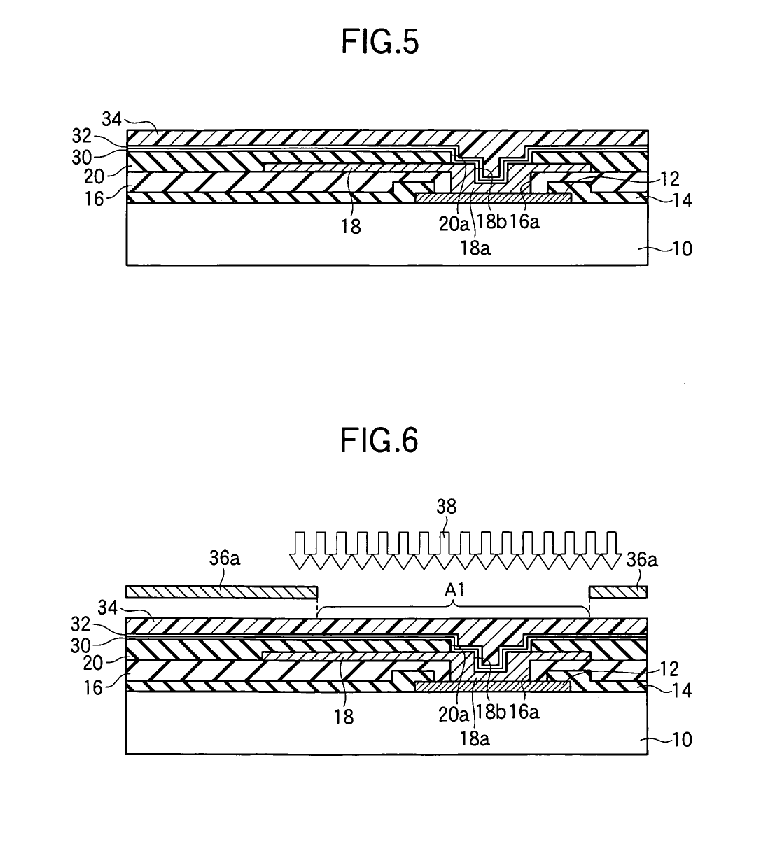

Next, referring to FIG. 5, a second seed layer 30 which will constitute a lower-side part of the second redistribution layer 22, a second conductive material layer 32 which will constitute a lower-side part of the second redistribution layer 22, and a resist film 34 are sequentially deposited on the first redistribution layer 18 and the second insulating layer 20. The second seed layer 30 is a base metal layer for giving conductivity to the surface of the second insulating layer 20 and increasing adhesive properties to the second insulating layer 20, and can be made of, for example, titanium (Ti) or copper (Cu) or the like. The second redistribution layer 22 including the second conductive material layer 32 can be made of, for example, Cu or the like. The second seed layer 30 and the second conductive material layer 32 can be formed by a film-forming method such as an electroless plating method, a sputtering method, or the like.

The resist film 34 is formed by a spin coating method or the like, and therefore an upper surface of the resist film 34 is a planarized surface. Therefore, a second thickness of the resist film 34 inside the second opening 20a and outside the recess 18b is larger than a first thickness of the resist film 34 on the second insulating layer 20 outside the second opening 20a. Furthermore, a third thickness of the resist film 34 inside the recess 18b in the first via 18a is much larger than the second thickness of the resist film 34 inside the second opening 20a and outside the recess 18b.

The resist film 34 is a plating resist used for forming the second redistribution layer 22, which will be described below, of a predetermined pattern through a plating process. The resist film 34 is, for example, a positive type photoresist (photosensitive film), a light-exposed part of which can be removed by etching through a developing process. Furthermore, the resist film 34 may be a novolac type photoresist or a chemically amplified photoresist.

If the novolac type photoresist is used as the resist film 34, g-line (a wavelength 436 nm) and i-line (a wavelength 365 nm) of a high pressure mercury lamp can be used as exposure light at the exposure processes. If the chemically amplified photoresist is used as the resist film 34, the laser light (a wavelength 248 nm) emitted from KrF excimer laser can be used as exposure light at the exposure processes.

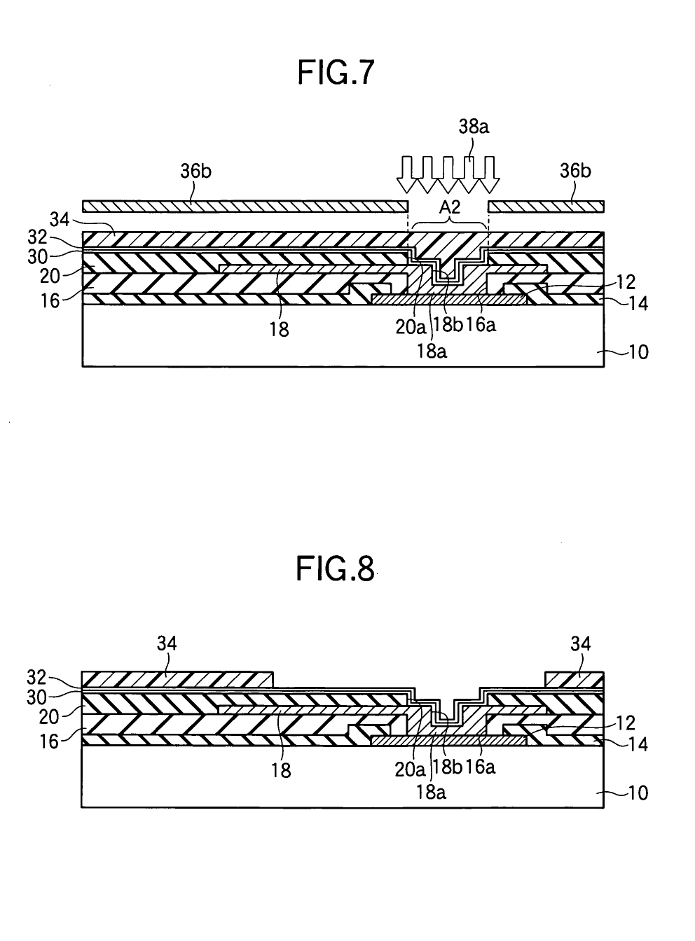

Next, referring to FIG. 6, at the first exposure process using a first light shielding mask 36a, a predetermined first area A1 of the resist film 34, where the second redistribution layer 22 is to be formed, is irradiated with exposure light 38a emitted from an exposure device (not shown in the figures). Furthermore, referring to FIG. 7, by the second exposure process using a light shielding mask 36b, a predetermined second area A2 of the resist film 34, which corresponds to an area where the second opening 20a of the resist film 34 is formed, is irradiated with exposure light 38b emitted from the exposure device.

With the above exposure processes, a part of the resist film 34 inside the second area A2, which is included in the first area A1, is subjected to the multiple light-exposure processes, and therefore the exposure light that has reached a deep position of the second area A2 in a thickness direction of the resist film 34 can be increased enough. In other words, the part of the resist film 34 inside the second opening 20a and outside the recess 18b of the first via 18a are light-exposed by enough large amount of the exposure light 38a, and the part of the resist film 34 inside the recess 18b of the first via 18a are exposed by enough large amount of the exposure light 38a and 38b, whereas excessive light exposing on a part of the resist film 34 outside the area for forming the second redistribution layer 22 can be prevented. Further, although in the above-described example, the exposure process of the second area A2 is performed after the exposure process of the first area A1, the exposure process of the first area A1 may be performed after the exposure process of the second area A2.

Furthermore, the second area A2 where the multiple light-exposure processes are performed may be set to a broader area than the area corresponding to an area where the second opening 20a is formed, as long as the second area A2 is inside the first area A1. However, if more than necessary broader area is subjected to the multiple light-exposure processes, a desired redistribution pattern cannot be obtained. It is preferable that the second area A2, where the above-described multiple light-exposure processes are performed, do not extend an area where the second opening 20a is formed in order to obtain a desired redistribution pattern, and it is more preferable that the second area A2 coincide with an area where the second opening 20a is formed. The second area A2 is set so that at least the resist film 34 inside the recess 18b of the first via 18a is subjected to the multiple light-exposure processes.

Next, referring to FIG. 8, the resist film 34 is developed. Through a developing process, the light-exposed part of the resist film 34 is removed by etching, thereby patterning the resist film 34 so as to have a desired redistribution pattern. In general, the developing process uses a strong alkaline developing solution such as TMAH (Tetramethylammonium hydroxide: N(CH₃)₄OH) or the like. In this embodiment, since enough amount of exposure light reached the deep portion in the thickness direction of the resist film 34, a part of the resist film 34 inside the second opening 20a and a part of the resist film 34 inside the recess 18b of the first via 18a can be removed completely. With the above processes, the resist film 34 inside the first area A1 where the second redistribution layer 22 is to be formed is completely removed, and an upper surface of the second conductive material layer 32 inside the first area A1 is exposed.

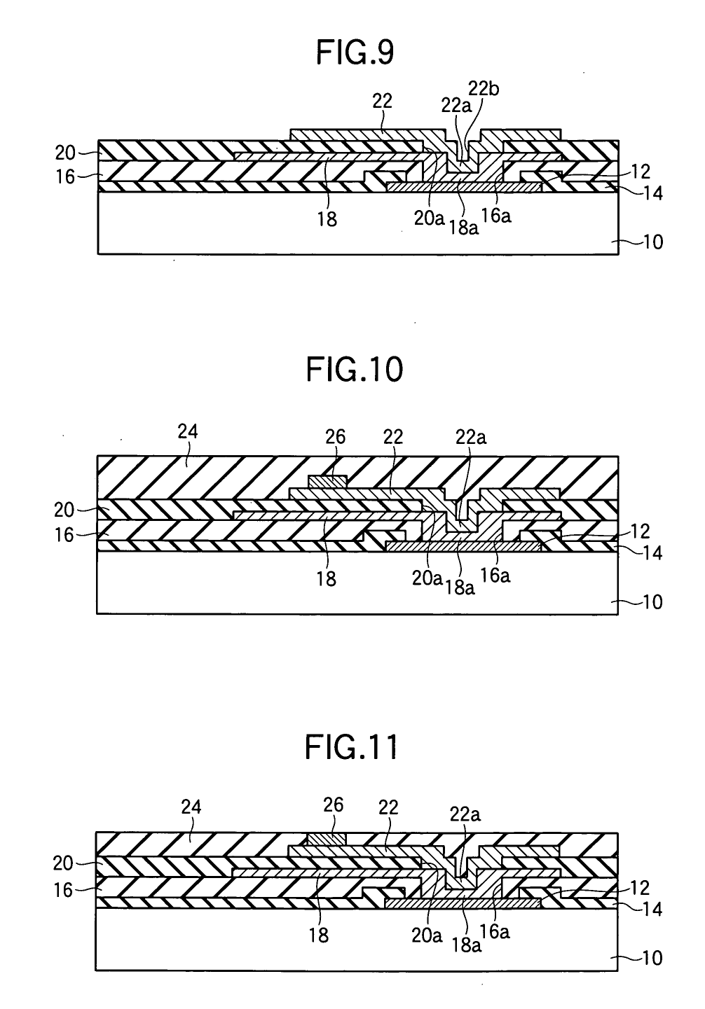

Next, the second redistribution layer 22 electrically connected to the first redistribution layer 18 is formed. Referring to FIG. 8 and FIG. 9, the exposed part of the second conductive material layer 32 caused to be grown through an electroless plating process or an electroplating process, so as to increase the thickness of the conductive material layer at wiring pattern portions of the second redistribution layer 22. The exposed second conductive material layer 32 is unified together with the second seed layer 30 as a lower layer and the conductive material layer caused to grow through a plating process, and as a result the second redistribution layer 22 electrically connected to the first redistribution layer 18 is formed on the first redistribution layer 18 and the second insulating layer 20.

Since the second redistribution layer 22 has the part disposed inside the recess 18b of the first via 18a and the second opening 20a, the part which is referred to as a second via 22a is lower than the upper surface of the part second insulating layer 20. The second via 22a has a step-like recess 22b around a center of an upper surface of the second via 22a. The first via 18a and the second via 22a constitute a stacked via structure including a plurality of stacked vias.

After that, as can be understood from FIG. 8 and FIG. 9, the resist film 34, a part of the second conductive material layer 32 outside an area where the second redistribution layer 22 is caused to grow, and a part of the second seed layer 30 outside the area where the second redistribution layer 22 is caused to grow are sequentially removed, and therefore fabricating processes of the second redistribution layer 22 are completed. In other words, in this process, the resist film 34, the part of the second conductive material layer 32 that was placed under the resist film 34 and the part of the second seed layer 30 that was placed under the resist film 34 are sequentially removed.

Next, referring to FIG. 10, a pillar-shaped post electrode 26 is formed so as to be electrically connected to the second redistribution layer 22. The post electrode 26 is made of a conductive material such as Cu or the like. Next, an insulating protective film 24 is formed so as to cover the second insulating layer 20, the second redistribution layer 22, and the post electrode 26. The protective film 24 is made of, for example, a polymer type insulating material or the like. The polymer type insulating material is preferably polyimide or the like, for example.

Next, referring to FIG. 11, an upper surface of the protective film 24 is subjected to a process by chemical mechanical polishing technology (CMP) or the like, until an upper surface of the post electrode 26 is exposed. With the above process, the post electrode 26 penetrating the protective film 24 is completed.

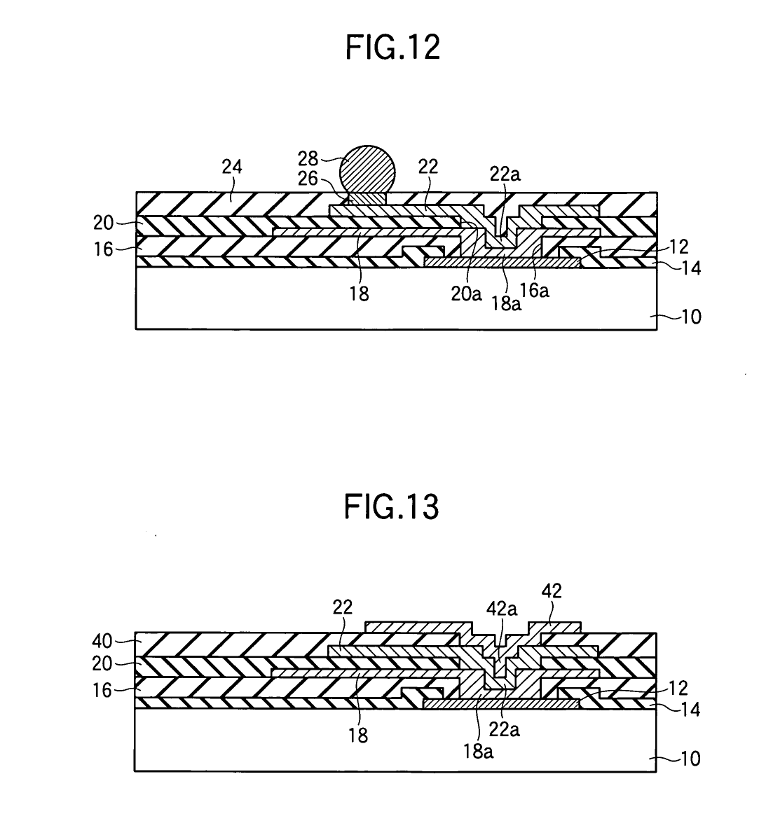

Finally, referring to FIG. 12, an external connecting terminal is formed as follows. The surface of the post electrode 26 is exposed from the upper surface of the protective film 24. A solder ball is fixed to the surface of the exposed post electrode 26, and constitutes an external connecting terminal 28.

With the above processes, a WCSP manufactured by the method of this embodiment can be obtained. Furthermore, a CSP can be obtained by singulating (or dicing) the semiconductor wafer 10 which has been subjected to the above processes to separate structures.

As has been described above, in this embodiment, in the process of forming the stacked via structure including the first redistribution layer 18 and the second redistribution layer 22, which are electrically connected through the first via 18a and the second via 22a, a part of the photo resist 34 having a large thickness is subjected to multiple light exposure processes. Accordingly, the exposure light can reach a deep portion of the photo resist 34, and the photo resist 34 on the first via 18a (including the photo resist 34 inside the recess 18b of the first via 18a) of the first redistribution layer 18 can be removed by etching completely.

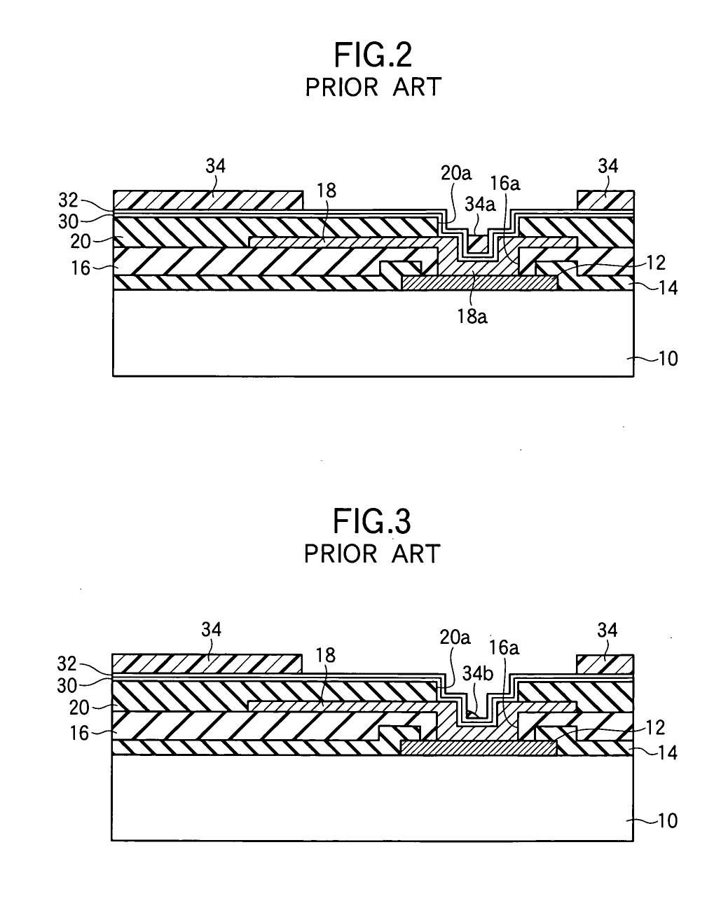

Since there is no residual of the photo resist 34 on the first via 18a (including the photo resist 34 inside the recess 18b of the first via 18a) of the first redistribution layer 18, the plating growth is not interfered by a residual (for example, parts 34a and 34b in FIG. 2 and FIG. 3) of the photo resist and the second redistribution layer 22 can be formed as a desired pattern. In other words, an electrically poor connection between the first redistribution layer 18 and the second redistribution layer 22 can be prevented in this embodiment, and therefore there occur few cases that the device manufactured by the method according to this embodiment has an electrically poor connection, that is, faulty components with an open-circuit fault.

Furthermore, in the above description, a case where the stacked via structure is a two-layer structure including the first redistribution layer 18 and the second redistribution layer 22 electrically connected to the first redistribution layer 18 has been described. However, the present invention can be applied to the other type of multi-layer structure such as a three-layer structure including a third insulating layer 40 and a third redistribution layer 42 with a third via 42a, for example, as illustrated in FIG. 13.

Those skilled in the art will recognize that the above embodiments can be modified in various ways within the scope of the invention, which is defined in the appended claims.

What is claimed is:

1. A method of manufacturing a semiconductor device comprising the steps of:
forming a first-insulating layer with a first opening on a semiconductor substrate;
forming a first redistribution layer having a first via inside the first opening on the semiconductor substrate and the first insulating layer, an upper surface of the first via having a recess;
forming a second insulating layer with a second opening on the first redistribution layer so that the second opening causes a part of the first redistribution layer including the recess to be exposed;
depositing a conductive material layer so as to cover the exposed part of the first redistribution layer;
depositing a photoresist film so as to cover the conductive material layer;
irradiating a first area of the photoresist film corresponding to an area where a second redistribution layer is to be formed with first exposure light, and irradiating a second area of the photoresist film with second exposure light, wherein the first area includes the second area and the second area includes an area corresponding to the first via;
developing the photoresist film to remove a part of the photoresist film inside the first area, thereby causing the conductive material layer to be exposed; and
causing the conductive material layer to grow through a plating process, thereby forming the second redistribution layer having a second via stacked on the first via.

2. The method according to claim 1, wherein the second area of the photoresist film is equal to or within an area corresponding to the second opening of the second insulating layer.

3. The method according to claim 1, further comprising a step of forming a third redistribution layer having a third via stacked on the second via.

4. The method according to claim 1, further comprising the steps of:
forming a post electrode on any of the first redistribution layer and the second redistribution layer;
forming a protective film so as to cover at least the first redistribution layer and the second redistribution layer;
forming an external connecting terminal on an upper surface of the post electrode.

5. The method according to claim 1, further comprising the steps of:
forming a electrode pad on the semiconductor substrate; and
forming a passivation film with a third opening on the semiconductor substrate so that the third opening causes a part of the electrode pad to be exposed;
wherein the step of forming the first insulating layer with the first opening is performed so that the first opening is formed inside the third opening and causes a part of the electrode pad to be exposed.
